(19) United States
(12) Patent Application Publication
(10) Pub. No.: US 2020/0111876 A1
(43) Pub. Date: Apr. 9, 2020

(54) ALGAN/GAN HETEROJUNCTION HEMT DEVICE COMPATIBLE WITH SI-CMOS PROCESS AND MANUFACTURING METHOD THEREFOR

(71) Applicant: SOUTH CHINA UNIVERSITY OF TECHNOLOGY, Guangdong (CN)

(72) Inventors: Hong WANG, Guangdong (CN); Quanbin ZHOU, Guangdong (CN); Qixin LI, Guangdong (CN)

(73) Assignee: SOUTH CHINA UNIVERSITY OF TECHNOLOGY, Guangdong (CN)

(21) Appl. No.: 16/499,855

(22) PCT Filed: Aug. 29, 2018
(86) PCT No.: PCT/CN2018/102821

§ 371 Date: Sep. 30, 2019

(30) Foreign Application Priority Data
Nov. 21, 2017 (CN) 201711169060.6

(51) Int. Cl. H01L 29/20; H01L 29/778; H01L 29/66

(52) U.S. Cl. CPC H01L 29/2003; H01L 29/66462; H01L 29/7787

(57) ABSTRACT

Disclosed are an AlGaN/GaN heterojunction HEMT device compatible with a Si-CMOS process and a manufacturing method therefor. The device comprises: an AlGaN/GaN heterojunction epitaxial layer, a passivation layer, a gate dielectric layer, a gold-free gate electrode and gold-free source and drain electrodes. The AlGaN/GaN heterojunction epitaxial layer comprises a substrate, a nitride nucleating layer, a nitride buffer layer, a GaN channel layer, an AlGaN intrinsic barrier layer and an AlGaN heavily-doped layer from bottom to top in sequence; the AlGaN heavily-doped layer generates charges by an ionized donor so as to compensate for a surface acceptor level of a semiconductor, thus suppressing a current collapse; and ohmic contact with an electrode is formed by low-temperature annealing; and the gold-free electrode prevents Au from polluting a Si-CMOS process line.

### BACKGROUND

### Technical Field

The present invention belongs to the field of semiconductor device technologies, and more particularly, to a method for manufacturing an AlGaN/GaN heterojunction HEMT device compatible with a Si-CMOS process, which can be used in the fields of power electronics, microwave communication and the like.

### Description of Related Art

With the development of modern weaponry, aerospace, nuclear energy, communication technology, automotive electronics and switching power supply, higher requirements are put forward for the performance of semiconductor devices. As a typical representative of wide bandgap semiconductor materials, a GaN-based material has the characteristics of large bandgap width, high electron saturation drift speed, high critical breakdown field strength, high thermal conductivity, good stability, corrosion resistance, radiation resistance and the like, and can be used for manufacturing an electronic device with high temperature, high frequency and high power. In addition, GaN also has excellent electronic characteristics and can form a modulation-doped AlGaN/GaN heterostructure with AlGaN, the structure can obtain electron mobility higher than 1500 cm2/Vs, peak electron velocity as high as 3×107 cm/s and saturated electron speed as high as 2×107 cm/s at room temperature, and obtain two-dimensional electron gas density higher than that of a second generation compound semiconductor heterostructure, which is regarded as an ideal material for developing a microwave power device. Therefore, the microwave power device based on an AlGaN/GaN heterojunction has very good application prospect in high-frequency and high-power wireless communication, radar and other fields. However, a HEMT device still faces many challenges, such as current collapse, threshold stability and device reliability and so on, and the current collapse refers to the phenomenon that the on-resistance of the device is increased after high-voltage off-state stress. One of the main reasons for this phenomenon is a more serious interface state or surface state in the HEMT device, and the electron concentration in the device channel is decreased due to defect trapping. Meanwhile, the higher cost limits the wide application of the HEMT device. One method to reduce the manufacturing cost of HEMT is to realize large-scale production of HEMT in a Si-CMOS process line. Then, several factors limit the processing of the HEMT device in a CMOS process line: 1. the pollution of Au to the CMOS process line is caused by gold contact metal used in ohmic and Schottky contact processes of conventional HEMT device; and 2. the ohmic process temperature of conventional HEMT device is relatively high, causing the pollution of Ga to the CMOS process line, and meanwhile, the high temperature ruptures an AlGaN/GaN epitaxial layer on a large-size silicon substrate, thus reducing product yield.

### SUMMARY

The present invention is intended to overcome the defects of the prior art above, double AlGaN layers are used in an AlGaN/GaN heterojunction, and a gold-free electrode process and a low-temperature ohmic process are combined, so that the current collapse of the HEMT device can be effectively suppressed, the performance of the device can be improved, and the process temperature can also be reduced and the process flow can be simplified, thus overcoming the technical bottleneck of the compatibility of the AlGaN/GaN heterojunction HEMT with a Si-CMOS process, and facilitating reducing the manufacturing cost of the AlGaN/GaN heterojunction HEMT. The object of the present invention is achieved through at least one of the following technical solutions.

An AlGaN/GaN heterojunction HEMT device compatible with a Si-CMOS process comprises an AlGaN/GaN heterojunction epitaxial layer, a passivation layer, a gate dielectric layer, a gold-free gate electrode and gold-free source and drain electrodes. The AlGaN/GaN heterojunction epitaxial layer comprises a substrate, a nitride nucleating layer, a nitride buffer layer, a GaN channel layer, an AlGaN intrinsic barrier layer and an AlGaN heavily-doped layer from bottom to top in sequence, the AlGaN heavily-doped layer generates charges by means of an ionized donor so as to compensate for a surface acceptor level of a semiconductor, thus suppressing a current collapse, and meanwhile, ohmic contact with the gold-free source and drain electrodes is formed by means of low-temperature annealing, and the gold-free electrode prevents Au from polluting a Si-CMOS process line.

Further, the substrate of the AlGaN/GaN heterojunction epitaxial layer is made of sapphire, silicon, silicon carbide or homoepitaxial GaN, the nitride nucleating layer is made of GaN or AlN, the nitride buffer layer is made of GaN, AlGaN or a gradually changed component AlGaN or a combination of GaN, AlGaN and a gradually changed component AlGaN, and two-dimensional electron gas with a high electron mobility is provided between the GaN channel layer and the AlGaN intrinsic barrier layer.

Further, a moore content of an element Al in the AlGaN intrinsic barrier layer is ranging from 0.2 to 0.3, a thickness of the AlGaN intrinsic barrier layer is ranging from 10 nm to 15 nm, and doping is not performed when the AlGaN intrinsic barrier layer is epitaxially grown.

Further, a moore content of an element Al in the AlGaN heavily-doped layer is ranging from 0.1 to 0.2, a thickness of the AlGaN heavily-doped layer is ranging from 5 nm to 10 nm, and a doping concentration of a donor impurity (such as Si) is ranging from 1×10¹⁸ cm⁻³ to 1×10²⁰ cm⁻³.

Further, the passivation layer is covered on the AlGaN heavily-doped layer, and is made of one of SiN, SiO₂ and SiON, or is a multi-layer structure combined by SiN, SiO₂ and SiON, and a thickness of the passivation layer is ranging from 100 nm to 200 nm.

Further, the gate dielectric layer is covered on the passivation layer, and is made of one of SiN, SiO₂, SiON, Ga₂O₃, Al₂O₃, AlN and HfO₂, or is a multi-layer structure combined by SiN, SiO₂, SiON, Ga₂O₃, Al₂O₃, AlN and HfO₂, and a thickness of the gate dielectric layer is ranging from 20 nm to 30 nm.

Further, the passivation layer under the gold-free gate electrode is removed, a bottom of the electrode is contacted with the gate dielectric layer, and the gate dielectric layer is arranged between the gold-free gate electrode and the AlGaN heavily-doped layer. Meanwhile, all or a part of the corresponding AlGaN heavily-doped layer under the gate electrode is oxidized into an oxide.

Further, the gold-free gate electrode is made of multi-layer metal, wherein bottom-layer metal is Ni or other metals with a higher work function, and surface-layer metal is W, TiW or TiN or other metals which are stable and not easy to be oxidized in air, thus forming a multi-layer metal system of Ni/W, Ni/TiW or Ni/TiN or other multi-layer metal systems.

Further, the gate dielectric layer and the passivation layer under the gold-free source and drain electrodes are removed, and bottoms of the gold-free source and drain electrodes are contacted with the AlGaN heavily-doped layer.

Further, the gold-free source and drain electrodes are made of multi-layer metal, wherein bottom-layer metal is Ti/Al or other multi-layer metals, and surface-layer metal is W, TiW or TiN or other metals which are stable and not easy to be oxidized in air, thus forming a multi-layer metal system of Ti/Al/Ti/W, Ti/Al/TiW or Ti/Al/Ti/TiN or other multi-layer metal systems, and forming ohmic contact with the AlGaN heavily-doped layer by means of low-temperature annealing process.

Preparation of the AlGaN/GaN heterojunction HEMT device compatible with the Si-CMOS process comprises the following steps of:
1) epitaxial growth: epitaxially growing the nitride nucleating layer, the nitride buffer layer, the GaN channel layer, the AlGaN intrinsic barrier layer and the AlGaN heavily-doped layer on the substrate in sequence by metal organic vapor deposition MOCVD, thus forming the AlGaN/GaN heterojunction epitaxial layer;
2) device isolation: defining an active region by photoetching process, covering and protecting the active region with a photoresist, removing the AlGaN/GaN heterojunction outside the active region by ICP or RIE etching, wherein an etching depth is greater than the AlGaN intrinsic barrier layer, and removing the AlGaN heavily-doped layer, the AlGaN intrinsic barrier layer and a part of the GaN channel layer so as to realize isolation among different devices;
3) passivation layer deposition: depositing the passivation layer with a certain thickness on the AlGaN/GaN heterojunction epitaxial layer;
4) gate electrode opening: defining a gold-free gate electrode pattern on the passivation layer by photoetching process, etching the passivation layer by ICP or RIE, and completely etching and removing the passivation layer under the gold-free gate electrode pattern; and performing oxidation treatment to the AlGaN heavily-doped layer exposed in the gate electrode pattern by ICP or RIE, thus generating an oxide or a nitrogen oxide;
5) gate dielectric layer: depositing the gate dielectric layer on the passivation layer to cover a surface of the whole device;
6) gate electrode: defining a gold-free gate electrode pattern by photoetching process, depositing a gold-free gate electrode metal film by electron beam evaporation or magnetron sputtering, and then forming the gold-free gate electrode by lift-off process;
7) source and drain electrodes: defining a gold-free source and drain electrode pattern on the passivation layer by photoetching process, etching the gate dielectric layer and the passivation layer by ICP or RIE, and completely etching and removing the gate dielectric layer and the passivation layer under the gold-free source and drain electrode pattern; and depositing a gold-free source and drain electrode metal film by electron beam evaporation or magnetron sputtering, and then forming the gold-free source and drain electrodes by lift-off process; and
8) low-temperature annealing: forming ohmic contact between metal of the gold-free source and drain electrodes and the AlGaN/GaN heterojunction epitaxial layer by annealing process.

Further, a moore content of an element Al in the AlGaN intrinsic barrier layer is ranging from 0.2 to 0.3, a thickness of the AlGaN intrinsic barrier layer is ranging from 10 nm to 15 nm, and doping is not performed when the layer is epitaxially grown; a moore content of an element Al in the AlGaN heavily-doped layer is ranging from 0.1 to 0.2, a thickness of the AlGaN heavily-doped layer is ranging from 5 nm to 10 nm, and a doping concentration of a donor impurity is 1×10¹⁸ cm⁻³ to 1×10²⁰ cm⁻³.

Further, the passivation layer is made of one of SiN, SiO₂ and SiON, or is a multi-layer structure combined by SiN, SiO₂ and SiON, a thickness of the passivation layer is ranging from 100 nm to 200 nm, and one of metal organic chemical vapor deposition MOCVD, plasma enhanced chemical vapor deposition PECVD and low pressure chemical vapor deposition LPCVD can be adopted as a deposition method.

Further, oxidation treatment refers to oxidizing all or a part of the AlGaN heavily-doped layer under the gate electrode by ICP or RIE using oxygen ions, and a generated oxide or nitrogen oxide is Al₂O₃, Ga₂O₃, AlSiON, AlON or any combination thereof.

Further, the gate dielectric layer is made of one of SiN, SiO₂, SiON, Ga₂O₃, Al₂O₃, AlN and HfO₂, or is a multi-layer structure combined by SiN, SiO₂, SiON, Ga₂O₃, Al₂O₃, AlN and HfO₂, a thickness of the gate dielectric layer is ranging from 20 nm to 30 nm, and one of plasma enhanced chemical vapor deposition PECVD and low pressure chemical vapor deposition LPCVD can be adopted as a deposition method.

Further, the gold-free gate electrode is made of multi-layer metal, wherein bottom-layer metal is Ni or other metals with a high work function, and surface-layer metal is W, TiW or TiN or other metals which are stable and not easy to be oxidized in air, thus forming a multi-layer metal system of Ni/W, Ni/TiW or Ni/TiN.

Further, the gold-free source and drain electrodes are made of multi-layer metal, wherein bottom-layer metal is Ti/Al or other multi-layer metals, and surface-layer metal is W, TiW or TiN or other metals which are stable and not easy to be oxidized in air, thus forming a multi-layer metal system of Ti/Al/Ti/W, Ti/Al/TiW or Ti/Al/Ti/TiN or other multi-layer metal systems, and forming ohmic contact with the AlGaN heavily-doped layer by means of low-temperature annealing process.

Further, low-temperature annealing process refers to placing a sample in a pure nitrogen atmosphere and annealing the sample at a temperature no more than 600° C. for 5 min to 10 min.

Compared with the prior art, the present invention has the following advantages and technical effects.

The device is an AlGaN/GaN heterojunction HEMT device compatible with a Si-CMOS process, double AlGaN layers are used in an AlGaN/GaN heterojunction, and the AlGaN heavily-doped layer generates charges by means of an ionized donor so as to compensate for a surface acceptor level of a semiconductor, thus suppressing the current collapse, and improving the performance of the device. A gold-free electrode process and a low-temperature ohmic process are combined, so that Au is prevented from polluting a Si-CMOS process line, and the process temperature can also be reduced and the process flow can be simplified, thus overcoming the technical bottleneck of the compatibility of the AlGaN/GaN heterojunction HEMT with a Si-CMOS process, and facilitating reducing the manufacturing cost of the AlGaN/GaN heterojunction HEMT.

### BRIEF DESCRIPTION OF THE DRAWINGS

FIG. 1 is a structure diagram of an AlGaN/GaN heterojunction HEMT device compatible with a Si-CMOS process in the present invention.

FIG. 2a to FIG. 2g are preparation process diagrams of an AlGaN/GaN heterojunction HEMT device compatible with a Si-CMOS process in an embodiment of the present invention.

### DESCRIPTION OF THE EMBODIMENTS

The specific implementation of the present invention is further described below with reference to the drawings and the embodiments, but the implementation and protection of the present invention are not limited to the drawings and the embodiments. It shall be noted that any processes or process parameters which are not specifically described below can all be implemented by those skilled in the art with reference to the prior art.

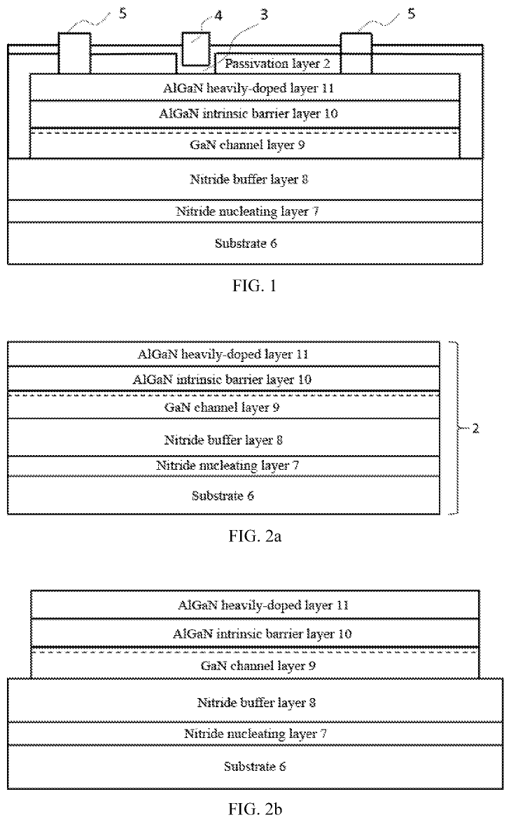

With reference to FIG. 1, the present invention discloses an AlGaN/GaN heterojunction HEMT device compatible with a Si-CMOS process and a manufacturing method therefor, and the device comprises an AlGaN/GaN heterojunction epitaxial layer 1, a passivation layer 2, a gate dielectric layer 3, a gold-free gate electrode 4 and gold-free source and drain electrodes 5. The AlGaN/GaN heterojunction epitaxial layer comprises a substrate 6, a nitride nucleating layer 7, a nitride buffer layer 8, a GaN channel layer 9, an AlGaN intrinsic barrier layer 10 and an AlGaN heavily-doped layer 11 from bottom to top in sequence.

The substrate 6 of the AlGaN/GaN heterojunction epitaxial layer 1 is made of silicon, the nitride nucleating layer 7 is made of AlN, the nitride buffer layer 8 is made of GaN, and two-dimensional electron gas with a high electron mobility is provided between the GaN channel layer 9 and the AlGaN intrinsic barrier layer 10. A moore content of an element Al in the AlGaN intrinsic barrier layer 10 is 0.25, a thickness of the AlGaN intrinsic barrier layer 10 is 15 nm, and doping is not performed when the AlGaN intrinsic barrier layer 10 is epitaxially grown. A moore content of an element Al in the AlGaN heavily-doped layer 11 is 0.15, a thickness of the AlGaN heavily-doped layer 11 is 5 nm, and a doping concentration of a donor impurity is 1×10²⁰ cm⁻³.

The passivation layer 2 is covered on the AlGaN heavily-doped layer 11, and is made of SiN, and a thickness of the passivation layer 2 is 200 nm. The gate dielectric layer 3 is covered on the passivation layer 2, and is made of SiN, and a thickness of the gate dielectric layer 3 is 30 nm. The passivation layer 2 under the gold-free gate electrode 4 is removed, a bottom of the electrode is contacted with the gate dielectric layer 3, and the gate dielectric layer 3 is arranged between the gold-free gate electrode 4 and the AlGaN heavily-doped layer 11. Meanwhile, a part of the corresponding AlGaN heavily-doped layer 11 under the gate electrode is oxidized into Al₂O₃. The gold-free gate electrode 4 is made of Ni/TiN=50/150 nm. The gate dielectric layer 3 and the passivation layer 2 under the gold-free source and drain electrodes 5 are removed, and bottoms of the gold-free source and drain electrodes 5 are contacted with the AlGaN heavily-doped layer 11. The gold-free source and drain electrodes 5 are made of Ti/Al/Ti/TiN=20/100/20/100 nm, and ohmic contact with the AlGaN heavily-doped layer 11 is formed by means of low-temperature annealing process.

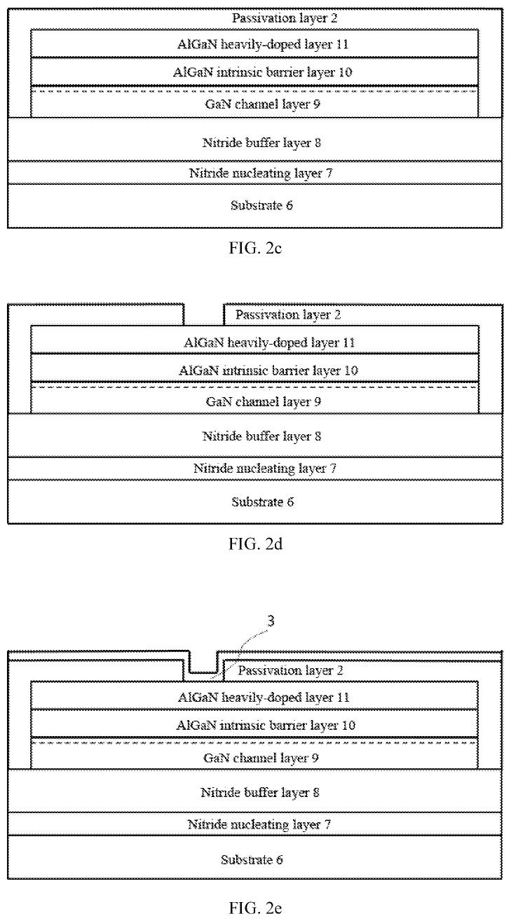

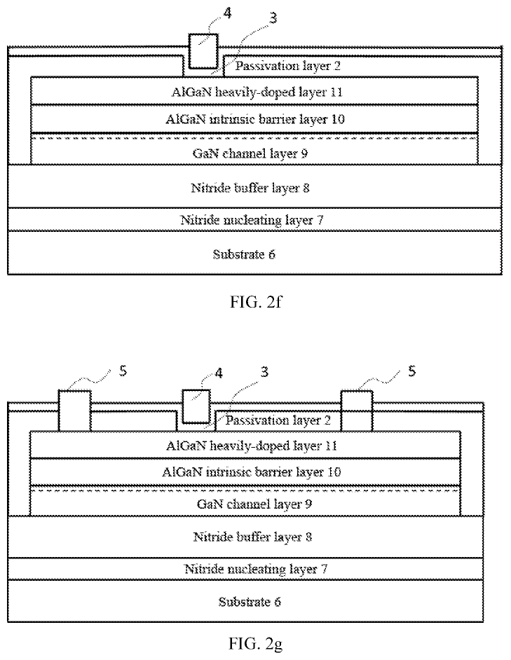

For illustration only, as shown in FIG. 2a to FIG. 2g, the specific implementation steps are as follows.

In the first step of epitaxial growth, the nitride nucleating layer 7, the nitride buffer layer 8, the GaN channel layer 9, the AlGaN intrinsic barrier layer 10 and the AlGaN heavily-doped layer 11 are epitaxially grown on the substrate 6 in sequence by metal organic vapor deposition MOCVD, thus forming the AlGaN/GaN heterojunction epitaxial layer 1, as shown in FIG. 2a, wherein a moore content of an element Al in the AlGaN intrinsic barrier layer 10 is 0.25, a thickness of the AlGaN intrinsic barrier layer 10 is 15 nm, and doping is not performed when the AlGaN intrinsic barrier layer 10 is epitaxially grown. A moore content of an element Al in the AlGaN heavily-doped layer 11 is 0.15, a thickness of the AlGaN heavily-doped layer 11 is 5 nm, and a doping concentration of a donor impurity is 1×10²⁰ cm⁻³.

In the second step of device isolation, an active region is defined by photoetching process, the active region is covered and protected with a photoresist, the AlGaN/GaN heterojunction outside the active region is removed by ICP etching, wherein an etching depth is greater than the AlGaN intrinsic barrier layer 10 and is 200 nm, and the AlGaN heavily-doped layer 11, the AlGaN intrinsic barrier layer 10 and a part of the GaN channel layer 9 are removed so as to realize isolation among different devices, as shown in FIG. 2b.

In the third step of passivation layer deposition, the passivation layer 2 is deposited on the AlGaN/GaN heterojunction epitaxial layer, as shown in FIG. 2c. The passivation layer 2 is made of SiN, a thickness of the passivation layer 2 is 200 nm, and low pressure chemical vapor deposition LPCVD is adopted as a deposition method.

In the fourth step of gate electrode opening, a gold-free gate electrode pattern is defined on the passivation layer by photoetching process, the passivation layer 2 is etched by ICP using fluorine-based ions, and the passivation layer 2 under the gold-free gate electrode pattern is completely etched and removed, as shown in FIG. 2d. Then, oxidation treatment is performed to the AlGaN heavily-doped layer 11 exposed in the gate electrode pattern by ICP using oxygen ions, thus generating an oxide Al₂O₃.

In the fifth step of gate dielectric layer, the gate dielectric layer 3 is deposited on the passivation layer 2 to cover a surface of the whole device, the gate dielectric layer 3 is made of SiN, a thickness of the gate dielectric layer 3 is 30 nm, and low pressure chemical vapor deposition LPCVD is adopted as a deposition method, as shown in FIG. 2e.

In the sixth step of gate electrode, a gold-free gate electrode pattern is defined by photoetching process, a gold-free gate electrode metal film Ni/TiN=50/150 nm is deposited by electron beam evaporation, and then the gold-free gate electrode 5 is formed by lift-off process, as shown in FIG. 2f.

In the seventh step of source and drain electrodes, a gold-free source and drain electrode pattern is defined on the passivation layer by photoetching process, the gate dielectric layer 3 and the passivation layer 2 are etched by ICP, and the gate dielectric layer 3 and the passivation layer 2 under the gold-free source and drain electrode pattern are completely etched and removed. A gold-free source and drain electrode metal film Ti/Al/Ti/TiN=20/100/20/100 nm is deposited by electron beam evaporation, and then the gold-free source and drain electrodes 5 are formed by lift-off process, as shown in FIG. 2g.

In the eighth step of low-temperature annealing, a sample is placed in a pure nitrogen atmosphere and annealed at a temperature 600° C. for 5 min, so that ohmic contact between metal of the gold-free source and drain electrodes and the AlGaN/GaN heterojunction epitaxial layer is formed.

The device is an AlGaN/GaN heterojunction HEMT device compatible with a Si-CMOS process, double AlGaN layers are used in an AlGaN/GaN heterojunction, and the AlGaN heavily-doped layer 11 generates charges by means of an ionized donor so as to compensate for a surface acceptor level of a semiconductor, thus suppressing the current collapse, and improving the performance of the device. A gold-free electrode process and a low-temperature ohmic process are combined, so that Au is prevented from polluting a Si-CMOS process line, the process temperature can also be reduced and the process flow can be simplified, thus overcoming the technical bottleneck of the compatibility of the AlGaN/GaN heterojunction HEMT with a Si-CMOS process, and facilitating reducing the manufacturing cost of the AlGaN/GaN heterojunction HEMT.

The embodiments above are merely the preferred embodiments of the present invention and do not constitute any limitation to the present invention. It is apparent that those skilled in the art, after understanding the content and principle of the present invention, can make various modifications and changes in form and detail according to the method of the present invention without departing from the principle and scope of the present invention, and all these modifications and changes based on the present invention are still included in the protection scope of the claims of the present invention.

1. An AlGaN/GaN heterojunction HEMT device compatible with a Si-CMOS process, comprising:
an AlGaN/GaN heterojunction epitaxial layer, a passivation layer, a gate dielectric layer, a gold-free gate electrode and gold-free source and drain electrodes, wherein the AlGaN/GaN heterojunction epitaxial layer comprises a substrate, a nitride nucleating layer, a nitride buffer layer, a GaN channel layer, an AlGaN intrinsic barrier layer and an AlGaN heavily-doped layer from bottom to top in sequence, the AlGaN heavily-doped layer generates charges by an ionized donor so as to compensate for a surface acceptor level of a semiconductor, thus suppressing a current collapse, and meanwhile, ohmic contact with the gold-free source and drain electrodes is formed by low-temperature annealing.

2. The AlGaN/GaN heterojunction HEMT device compatible with the Si-CMOS process according to claim 1, wherein the substrate of the AlGaN/GaN heterojunction epitaxial layer is made of sapphire, silicon, silicon carbide or homoepitaxial GaN, the nitride nucleating layer is made of GaN or AlN, the nitride buffer layer is made of one or a combination of two or more of GaN, AlGaN and a gradually changed component AlGaN, and two-dimensional electron gas is provided between the GaN channel layer and the AlGaN intrinsic barrier layer.

3. The AlGaN/GaN heterojunction HEMT device compatible with the Si-CMOS process according to claim 1, wherein a moore content of an element Al in the AlGaN intrinsic barrier layer is ranging from 0.2 to 0.3, a thickness of the AlGaN intrinsic barrier layer is ranging from 10 nm to 15 nm, and doping is not performed when the AlGaN intrinsic barrier layer is epitaxially grown; and a moore content of an element Al in the AlGaN heavily-doped layer is ranging from 0.1 to 0.2, a thickness of the AlGaN heavily-doped layer is ranging from 5 nm to 10 nm, and a doping concentration of a donor impurity is ranging from 1×10¹⁸ cm⁻³ to 1×10²⁰ cm⁻³.

4. The AlGaN/GaN heterojunction HEMT device compatible with the Si-CMOS process according to claim 1, wherein the passivation layer is covered on the AlGaN heavily-doped layer, and is made of one of SiN, SiO₂ and SiON, or is a multi-layer structure combined by SiN, SiO₂ and SiON, and a thickness of the passivation layer is ranging from 100 nm to 200 nm; and the gate dielectric layer is covered on the passivation layer, and is made of one of SiN, SiO₂, SiON, Ga₂O₃, Al₂O₃, AlN and HfO₂, or is a multi-layer structure combined by SiN, SiO₂, SiON, Ga₂O₃, Al₂O₃, AlN and HfO₂, and a thickness of the gate dielectric layer is ranging from 20 nm to 30 nm.

5. The AlGaN/GaN heterojunction HEMT device compatible with the Si-CMOS process according to claim 1, wherein the passivation layer under the gold-free gate electrode is removed, a bottom of the gold-free gate electrode is contacted with the gate dielectric layer, and the gate dielectric layer is arranged between the gold-free gate electrode and the AlGaN heavily-doped layer; meanwhile, all or a part of the corresponding AlGaN heavily-doped layer under the gate electrode is oxidized into an oxide; the gold-free gate electrode is made of multi-layer metal, wherein bottom-layer metal is Ni, and surface-layer metal is W, TiW or TiN which is stable and not easy to be oxidized in air, thus forming a multi-layer metal system of Ni/W, Ni/TiW or Ni/TiN.

6. The AlGaN/GaN heterojunction HEMT device compatible with the Si-CMOS process according to claim 1, wherein the gate dielectric layer and the passivation layer under the gold-free source and drain electrodes are removed, and bottoms of the gold-free source and drain electrodes are contacted with the AlGaN heavily-doped layer.

7. The AlGaN/GaN heterojunction HEMT device compatible with the Si-CMOS process according to claim 1, wherein the gold-free source and drain electrodes are made of multi-layer metal, wherein bottom-layer metal is multi-layer metal of Ti/Al, and surface-layer metal is W, TiW or TiN, thus forming a multi-layer metal system of Ti/Al/Ti/W, Ti/Al/TiW or Ti/Al/Ti/TiN, and forming ohmic contact with the AlGaN heavily-doped layer by low-temperature annealing process.

8. The AlGaN/GaN heterojunction HEMT device compatible with the Si-CMOS process according to claim 1, wherein a preparation process comprises the following steps of:
1) epitaxial growth: epitaxially growing the nitride nucleating layer, the nitride buffer layer, the GaN channel layer, the AlGaN intrinsic barrier layer and the AlGaN heavily-doped layer on the substrate in sequence by metal organic vapor deposition MOCVD, thus forming the AlGaN/GaN heterojunction epitaxial layer;
2) device isolation: defining an active region by photoetching process, covering and protecting the active region with a photoresist, removing the AlGaN/GaN heterojunction outside the active region by ICP or RIE etching, wherein an etching depth is greater than the AlGaN intrinsic barrier layer, and removing the AlGaN heavily-doped layer, the AlGaN intrinsic barrier layer and a part of the GaN channel layer so as to realize isolation among different devices;
3) passivation layer deposition: depositing the passivation layer with a certain thickness on the AlGaN/GaN heterojunction epitaxial layer;
4) gate electrode opening: defining a gold-free gate electrode pattern on the passivation layer by photoetching process, etching the passivation layer by ICP or RIE, and completely etching and removing the passivation layer under the gold-free gate electrode pattern; and performing oxidation treatment to the AlGaN heavily-doped layer exposed in the gate electrode pattern by ICP or RIE, thus generating an oxide or a nitrogen oxide;
5) gate dielectric layer: depositing the gate dielectric layer on the passivation layer to cover a surface of the whole device;
6) gate electrode: defining a gold-free gate electrode pattern by photoetching process, depositing a gold-free gate electrode metal film by electron beam evaporation or magnetron sputtering, and then forming the gold-free gate electrode by lift-off process;
7) source and drain electrodes: defining a gold-free source and drain electrode pattern on the passivation layer by photoetching process, etching the gate dielectric layer and the passivation layer by ICP or RIE, and completely etching and removing the gate dielectric layer and the passivation layer under the gold-free source and drain electrode pattern; and depositing a gold-free source and drain electrode metal film by electron beam evaporation or magnetron sputtering, and then forming the gold-free source and drain electrodes by lift-off process;
8) low-temperature annealing: forming ohmic contact between metal of the gold-free source and drain electrodes and the AlGaN/GaN heterojunction epitaxial layer by annealing process.

9. A method for manufacturing the AlGaN/GaN heterojunction HEMT device compatible with the Si-CMOS process according to claim 1, wherein a moore content of an element Al in the AlGaN intrinsic barrier layer is ranging from 0.2 to 0.3, a thickness of the AlGaN intrinsic barrier layer is ranging from 10 nm to 15 nm, and doping is not performed when the layer is epitaxially grown; a moore content of an element Al in the AlGaN heavily-doped layer is 0.1 to 0.2, a thickness of the AlGaN heavily-doped layer is ranging from 5 nm to 10 nm, and a doping concentration of a donor impurity is ranging from 1×10¹⁸ cm⁻³ to 1×10²⁰ cm⁻³; the passivation layer is made of one of SiN, SiO₂ and SiON, or is a multi-layer structure combined by SiN, SiO₂ and SiON, a thickness of the passivation layer is ranging from 100 nm to 200 nm, and one of metal organic chemical vapor deposition MOCVD, plasma enhanced chemical vapor deposition PECVD and low pressure chemical vapor deposition LPCVD is adopted as a deposition method; the gate dielectric layer is made of one of SiN, SiO₂, SiON, Ga₂O₃, Al₂O₃, AlN and HfO₂, or is a multi-layer structure combined by SiN, SiO₂, SiON, Ga₂O₃, Al₂O₃, AlN and HfO₂, a thickness of the gate dielectric layer is ranging from 20 nm to 30 nm, and one of plasma enhanced chemical vapor deposition PECVD and low pressure chemical vapor deposition LPCVD is adopted as a deposition method; bottom-layer metal is Ti/Al multi-layer metal, and surface-layer metal is W, TiW or TiN, thus forming a multi-layer metal system of Ti/Al/Ti/W, Ti/Al/TiW or Ti/Al/Ti/TiN, and forming ohmic contact with the AlGaN heavily-doped layer by low-temperature annealing process.

10. The method according to claim 9, wherein oxidation treatment refers to oxidizing all or a part of the AlGaN heavily-doped layer under the gate electrode by ICP or RIE using oxygen ions, and a generated oxide or nitrogen oxide is Al₂O₃, Ga₂O₃, AlSiON, AlON or any combination thereof; and low-temperature annealing refers to placing a sample in a pure nitrogen atmosphere and annealing the sample at a temperature no more than 600° C. for 5 min to 10 min.
